(19) United States
(12) Patent Application Publication
(10) Pub. No.: US 2021/0059058 A1
(43) Pub. Date: Feb. 25, 2021

(54) MULTILAYER CIRCUIT BOARD AND METHOD FOR MANUFACTURING THE SAME

(71) Applicants: Avary Holding (Shenzhen) Co., Limited., Shenzhen (CN); QING DING PRECISION ELECTRONICS (HUAIAN) CO.,LTD, Huai an (CN)

(72) Inventors: HSIAO-TING HSU, New Taipei (TW); MING-JAAN HO, New Taipei (TW); XIAN-QIN HU, Shenzhen (CN); FU-YUN SHEN, Shenzhen (CN); WEN-ZHU WEI, Shenzhen (CN)

(21) Appl. No.: 16/583,567

(22) Filed: Sep. 26, 2019

(30) Foreign Application Priority Data
Aug. 23, 2019 (CN) 201910785810.5

(51) Int. Cl. H05K 3/46; H05K 1/11; H05K 1/03; H05K 3/40

(52) U.S. Cl. CPC H05K 3/4688; H05K 1/115; H05K 1/119; H05K 1/036; H05K 2203/068; H05K 3/4069; H05K 2201/0141; H05K 2201/09509; H05K 3/4602

(57) ABSTRACT

A multilayer circuit board includes a first connecting wiring board comprising a first bonding layer and a liquid crystal polymer formed on the first bonding layer. The first bonding layer comprises a first insulating filler. A fusion temperature of the first bonding layer is less than a fusion temperature of the liquid crystal polymer. The multilayer circuit board further includes a first wiring board and a second wiring board disposed on opposite sides of the first connecting wiring board. The first wiring board is combined with the first bonding layer. A method for manufacturing such multilayer circuit board is also provided.

### FIELD

The subject matter herein generally relates to a circuit, especially relates to a multilayer circuit board and a method for manufacturing the multilayer circuit board.

### BACKGROUND

Materials with a low dielectric loss factor and a low dielectric constant such as liquid crystal polymer are usually applied in a high frequency circuit board as a dielectric layer to wrapped signal wirings. However, due to a fluidity of the liquid crystal polymer, after heated, a thickness of the dielectric layer may be easily changed and wiring layers may be easily driven by the dielectric layer.

Therefore, there is room for improvement within the art.

### BRIEF DESCRIPTION OF THE DRAWINGS

Implementations of the present disclosure will now be described, by way of embodiments, with reference to the attached figures.

FIG. 1 is a flowchart of an embodiment of a method for manufacturing a multilayer circuit board.

FIG. 2 is a cross-sectional view of an embodiment of a first bonding sheet including a first bonding layer and a first removable film.

FIG. 3 is a cross-sectional view showing a copper clad pressed on the first bonding sheet of FIG. 2.

FIG. 4 is a cross-sectional view showing at least one blind via defined on the first bonding sheet and the copper clad of FIG. 3.

FIG. 5 is a cross-sectional view showing a conductive paste filling the at least one blind via of FIG. 4.

FIG. 6 is a cross-sectional view of an embodiment of a connecting wring board.

FIG. 7 is a cross-sectional view showing the connecting wring board of FIG. 6, a first wring board, and a second wring board.

FIG. 8 is a cross-sectional view of an embodiment of a multilayer circuit board.

FIG. 9 is a flowchart of another embodiment of a method for manufacturing a multilayer circuit board.

FIG. 10 is a cross-sectional view showing a first bonding sheet, a copper clad and a second bonding sheet stacked orderly and connected together.

FIG. 11 is a cross-sectional view showing at least one through hole defined to pass through the first bonding sheet, the copper clad and the second bonding sheet of FIG. 10.

FIG. 12 is a cross-sectional view showing a conductive paste filling the through hole of FIG. 11.

FIG. 13 is a cross-sectional view of an embodiment of a multilayer circuit board.

FIG. 14 is a cross-sectional view of an embodiment of a multilayer circuit board.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

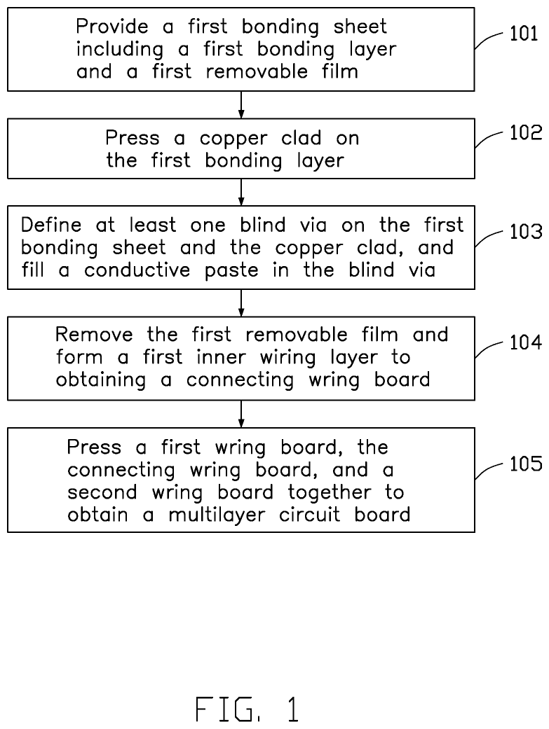

FIG. 1 illustrates a flowchart of a method in accordance with an embodiment. The method for manufacturing a multilayer circuit board 100 (shown in FIG. 7) is provided by way of embodiments, as there are a variety of ways to carry out the method. Each block shown in FIG. 1 represents one or more processes, methods, or subroutines carried out in the method. Furthermore, the illustrated order of blocks can be changed. Additional blocks may be added or fewer blocks may be utilized, without departing from this disclosure. The method can begin at block 101.

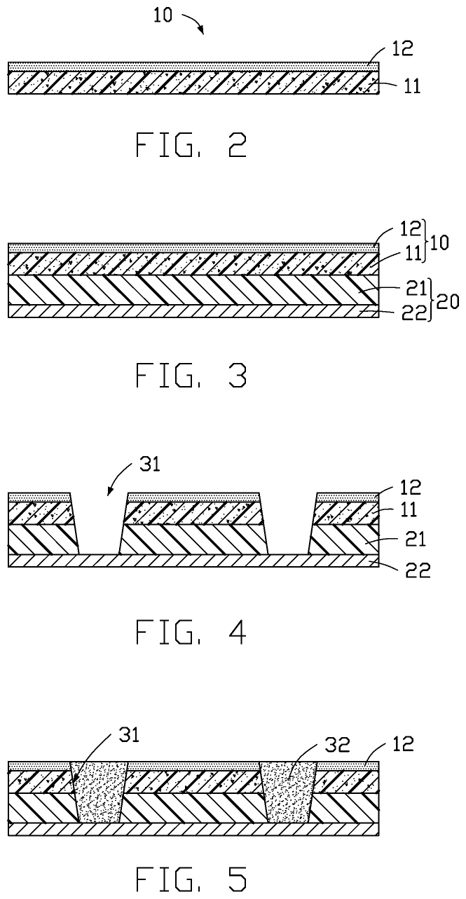

At block 101, referring to FIG. 2, a first bonding sheet 10 is provided.

In at least one embodiment, the first bonding sheet 10 includes a first bonding layer 11 and a first removable film 12 formed on the first bonding layer 11.

The first bonding layer 11 includes a first resin and a first insulating filler dispersed in the first resin. The first insulating filler serves to reduce a fluidity of the first bonding layer 11.

In at least one embodiment, the first bonding layer 11 includes 15% by mass to 50% by mass of the first insulating filler.

In at least one embodiment, the first insulating filler is granular or fibrous. When the first insulating filler is granular, a diameter of the first insulating filler is 100 nm and 2 μm. When the first insulating filler is fibrous, a length of the first insulating filler is 100 nm and 2 μm.

In at least on embodiment, the first insulating filler may be silicon dioxide of different shapes and sizes.

The first resin may be made of a thermoplastic material having a low dielectric constant Dₖ₁ and a low dielectric loss factor D_{f1}. The thermoplastic material may be selected from a group consisting of liquid crystal polymer, modified polyimide, polyimide, epoxy resin, polyphenylene sulfide, polytetrafluoroethylene, and any combination thereof.

In at least one embodiment, Dₖ₁ of the first resin and D_{f1} of the first resin satisfy the following conditions: 2.1≤Dₖ₁≤3.3, and 0.002≤D_{f1}≤0.01.

In at least one embodiment, the first bonding layer 11 has a thickness of 12 μm to 50 μm.

At block 102, referring to FIG. 3, a copper clad 20 is pressed on a surface of the first bonding layer 11 facing away from the first removable film 12.

In at least one embodiment, the copper clad 20 includes an insulating layer 21 on the first bonding layer 11 and a first metal foil 22 on a surface of the insulating layer 21 facing away from the first bonding layer 11. A fusion temperature of the first bonding layer 11 is less than a fusion temperature of the insulating layer 21, and the fusion temperature of the insulating layer 21 is greater than a pressing temperature.

The insulating layer 21 may be made of a thermoplastic material having a low dielectric constant Dₖ₂ and a low dielectric loss factor D_{f2}. The thermoplastic material may be selected from a group consisting of liquid crystal polymer, modified polyimide, polyimide, epoxy resin, polyphenylene sulfide, polytetrafluoroethylene, and any combination thereof.

In at least one embodiment, Dₖ₂ of the insulating layer 21 and D_{f2} of the insulating layer 21 satisfy the following conditions: 2.1≤Dₖ₂≤3.3, and 0.002≤D_{f2}≤0.01.

In at least one embodiment, the insulating layer 21 has a thickness of 25 μm to 100 μm.

Preferably, the thickness of the first bonding layer 11 is less than the thickness of the insulating layer 21.

At block 103, referring to FIGS. 4 and 5, at least one blind via 31 is defined on the first bonding sheet 10 and the copper clad 20, a conductive paste 32 fills the blind via 31 and electrically connects to the first metal foil 22.

In at least one embodiment, each blind via 31 passes through the first bonding sheet 10 and the insulating layer 21.

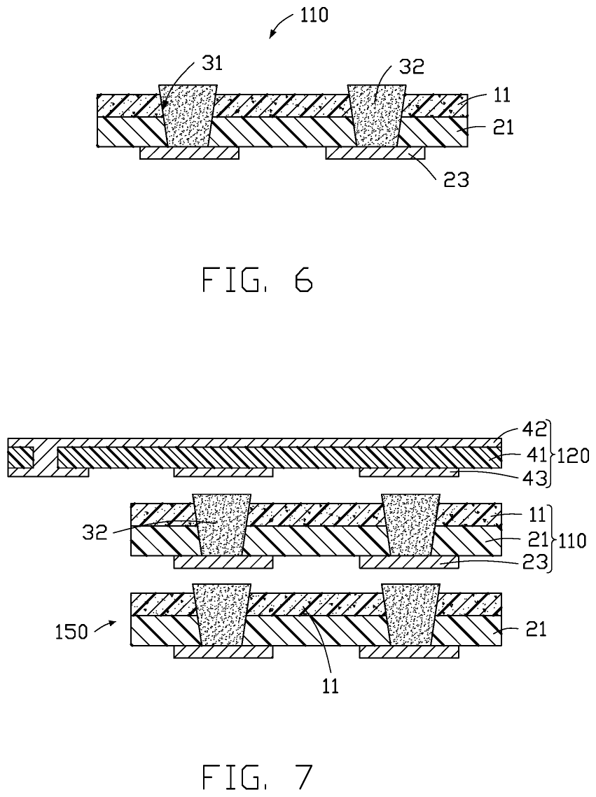

At block 104, referring to FIG. 6, the first removable film 12 is removed, and a first inner wiring layer 23 is formed by the first metal foil 22, thereby obtaining a connecting wiring board 110.

The conductive paste 32 protrudes from a surface of the first bonding layer 11 facing away from the insulating layer 21. In at least one embodiment, a height of the conductive paste 32 protruding from the surface of the first bonding layer 11 facing away from the insulating layer 21 is greater than 10 μm.

In at least one embodiment, a diameter of the blind via 31 is 75 mm to 150 mm.

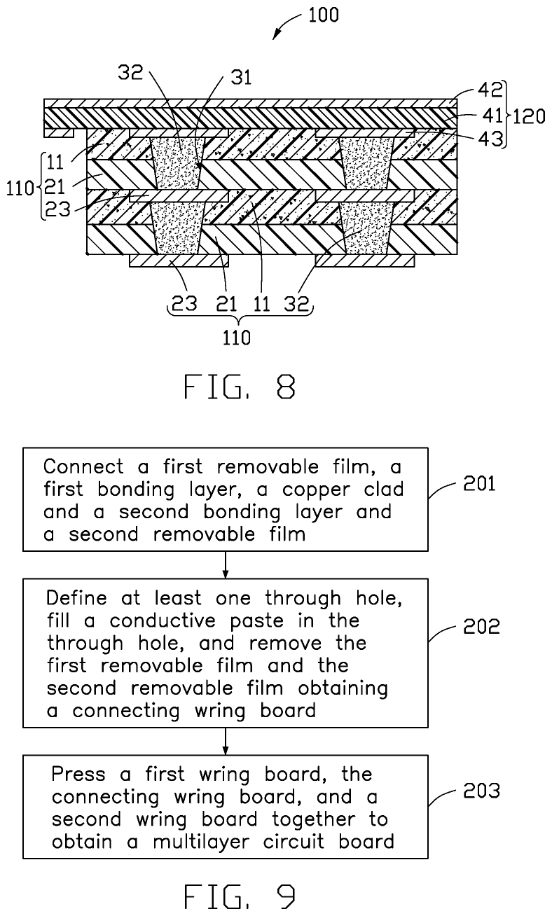

At block 105, referring to FIGS. 7 and 8, a first wiring board 120, the connecting wiring board 110 and a second wiring board 150 are stacked orderly and pressed together to obtain the multilayer circuit board 100.

The first wiring board 120 may be a flexible circuit board, a rigid circuit board or a flexible-rigid circuit board.

In at least one embodiment, the first wiring board 120 includes a first dielectric layer 41, a first outer wiring layer 43 and a second metal foil 42. The first outer wiring layer 43 and the second metal foil 42 are formed on opposite surfaces of the first dielectric layer 41, respectively. The first bonding layer 11 covers the first outer wiring layer 43 and is combined with the first dielectric layer 41.

In another embodiment, the first wiring board 120 may include other dielectric layers and other wiring layers.

In another embodiment, the second metal foil 42 may be replaced by a wiring layer.

Preferably, a thickness of the insulating layer 21 is less than a thickness of the first dielectric layer 41.

In at least one embodiment, a structure of the second wiring board 150 is the same with the structure of the connecting wiring board 110. The first bonding layer 11 of the second wiring board 150 covers the first inner wiring layer 23 and is combined with the insulating layer 21.

In at least one embodiment, a portion of the first wiring board 120 protrudes from the connecting wiring board 110 to expose from the connecting wiring board 110. The portion of the first wiring board 120 serves to carry at least one electronic element, and transmit an electrical signal between the electronic element and the connecting wiring board 110.

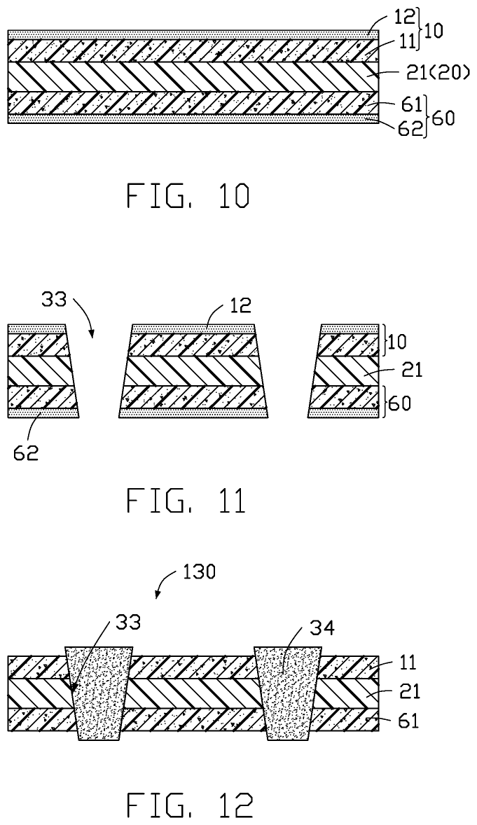

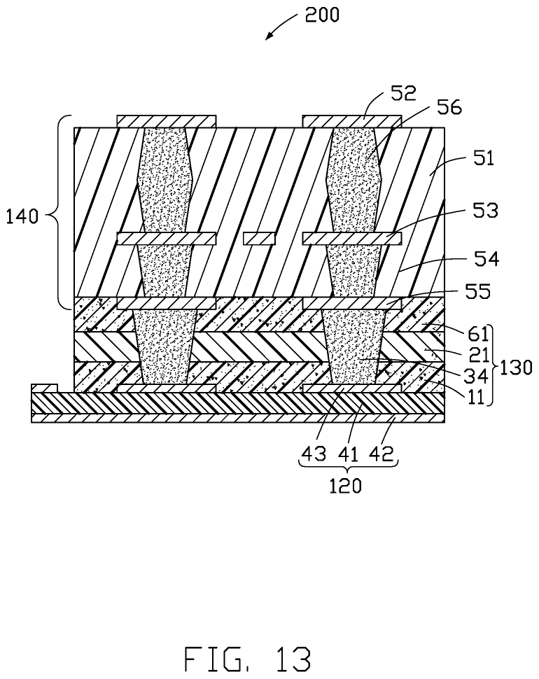

FIG. 9 illustrates a flowchart of a method in accordance with another embodiment. The method for manufacturing a multilayer circuit board 200 (shown in FIG. 13) is provided by way of embodiments, as there are a variety of ways to carry out the method. Each block shown in FIG. 9 represents one or more processes, methods, or subroutines carried out in the method. Furthermore, the illustrated order of blocks can be changed. Additional blocks may be added or fewer blocks may be utilized, without departing from this disclosure. The method can begin at block 201.

At block 201, referring to FIG. 10, a first bonding sheet 10, a copper clad 20 and a second bonding sheet 60 are stacked orderly and connected together.

In at least one embodiment, the first bonding sheet 10 includes a first bonding layer 11 and a first removable film 12 formed on the first bonding layer 11.

The first bonding layer 11 includes a first resin and a first insulating filler dispersed in the first resin. The first insulating filler serves to reduce a fluidity of the first bonding layer 11.

In at least one embodiment, the first bonding layer 11 includes 15% by mass to 50% by mass of the first insulating filler.

In at least one embodiment, the first insulating filler is granular or fibrous. When the first insulating filler is granular, a diameter of the first insulating filler is 100 nm and 2 μm. When the first insulating filler is fibrous, a length of the first insulating filler is 100 nm and 2 μm.

In at least on embodiment, the first insulating filler may be silicon dioxide of different shapes and sizes.

The first resin may be made of a thermoplastic material having a low dielectric constant Dₖ₁ and a low dielectric loss factor D_{f1}. The thermoplastic material may be selected from a group consisting of liquid crystal polymer, modified polyimide, polyimide, epoxy resin, polyphenylene sulfide, polytetrafluoroethylene, and any combination thereof.

In at least one embodiment, Dₖ₁ of the first resin and D_{f1} of the first resin satisfy the following conditions: 2.1≤Dₖ₁≤3.3, and 0.002≤D_{f1}≤0.01.

In at least one embodiment, the first bonding layer 11 has a thickness of 12 μm to 50 μm.

A structure of the second bonding sheet 60 is the same with a structure of the first bonding sheet 10. The second bonding sheet 60 includes a second bonding layer 61 and a second removable film 62 formed on the second bonding layer 61.

In at least one embodiment, the second bonding layer 61 includes a second resin and a second insulating filler dispersed in the second resin. The second insulating filler serves to reduce a fluidity of the second bonding layer 61.

In at least one embodiment, the second bonding layer 61 includes 15% by mass to 50% by mass of the second insulating filler.

In at least one embodiment, the second insulating filler is granular or fibrous. When the second insulating filler is granular, a diameter of the second insulating filler is 100 nm and 2 μm. When the second insulating filler is fibrous, a length of the second insulating filler is 100 nm and 2 μm.

In at least on embodiment, the second insulating filler may be silicon dioxide of different shapes and sizes.

The second resin may be made of a thermoplastic material having a low dielectric constant Dₖ₃ and a low dielectric loss factor D_{f3}. The thermoplastic material may be selected from a group consisting of liquid crystal polymer, modified polyimide, polyimide, epoxy resin, polyphenylene sulfide, polytetrafluoroethylene, and any combination thereof.

In at least one embodiment, Dₖ₃ of the second resin and D_{f3} of the second resin satisfy the following conditions: 2.1≤Dₖ₃≤3.3, and 0.002≤D_{f3}≤0.01.

In at least one embodiment, the second bonding layer 61 has a thickness of 12 μm to 50 μm.

Preferably, a composition of the second bonding layer 61 is the same as a composition of the first bonding layer 11 to obtain a better flatness.

In at least one embodiment, the copper clad 20 includes an insulating layer 21. A fusion temperature of the first bonding layer 11 and a fusion temperature of the second bonding layer 61 are less than a fusion temperature of the insulating layer 21, respectively. The fusion temperature of the insulating layer 21 is greater than a pressing temperature. The insulating layer 21 is formed on a surface of the first bonding layer 11 facing away from the first removable film 12. A surface of the second bonding layer 61 facing away the second removable film 62 is bonded to a surface of the insulating layer 21 facing away the first bonding layer 11.

The insulating layer 21 may be made of a thermoplastic material having a low dielectric constant Dₖ₂ and a low dielectric loss factor D_{f2}. The thermoplastic material may be selected from a group consisting of liquid crystal polymer, modified polyimide, polyimide, epoxy resin, polyphenylene sulfide, polytetrafluoroethylene, and any combination thereof.

In at least one embodiment, Dₖ₂ of the insulating layer 21 and D_{f2} of the insulating layer 21 satisfy the following conditions: 2.1≤Dₖ₂≤3.3, and 0.002≤D_{f2}≤0.01.

In at least one embodiment, the insulating layer 21 has a thickness of 25 μm to 100 μm.

Preferably, the thickness of the first bonding layer 11 and the thickness of the second bonding layer 61 are less than the thickness of the insulating layer 21, respectively.

At block 202, referring to FIGS. 11 and 12, at least one through hole 33 is defined to pass through the first bonding sheet 10, the copper clad 20 and the second bonding sheet 60, a conductive paste 34 fills the through hole 33, the first removable film 12 and the second removable film 62 are removed, thereby obtaining a connecting board 130.

At block 203, referring to FIG. 13, a first wiring board 120, the connecting wiring board 130 and a second wiring board 140 are stacked orderly and pressed together to obtain the multilayer circuit board 200.

The first wiring board 120 and the second wiring board 140 may be a flexible circuit board, a rigid circuit board or a flexible-rigid circuit board, respectively. In at least one embodiment, at least one electronic element may be amounted on at least one of the first wiring board 120 and the second wiring board 140.

In at least one embodiment, a portion of the first wiring board 120 protrudes from the connecting wiring board 130 to expose from the connecting wiring board 130. The portion of the first wiring board 120 serves to carry at least one electronic element, and transmit an electrical signal between the electronic element and the connecting wiring board 130.

In at least one embodiment, the first wiring board 120 includes a first dielectric layer 41, a first outer wiring layer 43 and a second metal foil 42. The first outer wiring layer 43 and the second metal foil 42 are formed on opposite surfaces of the first dielectric layer 41, respectively. The first bonding layer 11 covers the first outer wiring layer 43 and is combined with the first dielectric layer 41.

Preferably, a thickness of the insulating layer 21 is less than a thickness of the first dielectric layer 41.

In another embodiment, the first wiring board 120 may include other dielectric layers and other wiring layers.

In another embodiment, the second metal foil 42 may be replaced by a wiring layer or be omitted.

In at least one embodiment, the second wiring board 140 includes a third outer wiring layer 52, an second inner wiring layer 53, and a second outer wiring layer 55 stacked orderly and spaced. The second wiring board 140 further includes a second dielectric layer 54. The third outer wiring layer 52 and the second outer wiring layer 55 are located on opposite sides of the second dielectric layer 54. The second inner wiring layer 53 is embedded in the second dielectric layer 54, and wrapped by the second dielectric layer 54.

The second dielectric layer 54 is combined with the second bonding layer 61, the second outer wiring layer 55 is wrapped by the second dielectric layer 54 and the second bonding layer 61.

In another embodiment, the second wiring board 140 may include other dielectric layers and other wiring layers, or may only include the second outer wiring layer 55 and the second dielectric layer 54 but without the third outer wiring layer 52 and the second inner wiring layer 53.

In at least one embodiment, a material of the first dielectric layer 41 and a material of the second dielectric layer 54 may be respectively selected from a group consisting of liquid crystal polymer, modified polyimide, polyimide, epoxy resin, polyphenylene sulfide, polytetrafluoroethylene, and any combination thereof.

Preferably, a dielectric constant of the first dielectric layer 41 and a dielectric constant of the second dielectric layer 54 are between 2.1 and 3.3, respectively. A dielectric loss factor of the first dielectric layer 41 and a dielectric loss factor of the second dielectric layer 54 are between 0.002 and 0.01, respectively.

A fusion temperature of the first bonding layer 11 is less than a fusion temperature of the first dielectric layer 41 and less than a fusion temperature of the second dielectric layer 54.

Depending on the embodiment, certain of the steps of methods described may be removed, others may be added, and the sequence of steps may be altered. It is also to be understood that the description and the claims drawn to a method may include some indication in reference to sequential steps. However, the indication used is only to be viewed for identification purposes and not as a suggestion as to an order for the steps.

FIG. 8 illustrates an embodiment of a multilayer circuit board 100. The multilayer circuit board 100 includes a first wiring board 120, a connecting wiring board 110 and a second wiring board 150 are stacked orderly.

In at least one embodiment, the connecting wiring board 110 includes a first bonding layer 11, an insulating layer 21, and a first inner wiring layer 23 stacked orderly. The connecting wiring board 110 further includes at least one hole 32 passing through the first bonding layer 11 and the insulating layer 21 and exposing the first inner wiring layer 23. A conductive paste 32 fills the blind via 31 to electrically connects to the first inner wiring layer 23.

In another embodiment, the first inner wiring layer 23 may be omitted.

The first bonding layer 11 includes a first resin and a first insulating filler dispersed in the first resin. The first insulating filler serves to reduce a fluidity of the first bonding layer 11. In at least one embodiment, the first bonding layer 11 includes 15% by mass to 50% by mass of the first insulating filler.

The first insulating filler is granular or fibrous. When the first insulating filler is granular, a diameter of the first insulating filler is 100 nm and 2 μm. When the first insulating filler is fibrous, a length of the first insulating filler is 100 nm and 2 μm. In at least on embodiment, the first insulating filler may be silicon dioxide of different shapes and sizes.

The first resin may be made of a thermoplastic material having a low dielectric constant Dₖ₁ and a low dielectric loss factor D_{f1}. The thermoplastic material may be selected from a group consisting of liquid crystal polymer, modified polyimide, polyimide, epoxy resin, polyphenylene sulfide, polytetrafluoroethylene, and any combination thereof.

In at least one embodiment, Dₖ₁ of the first resin and D_{f1} of the first resin satisfy the following conditions: 2.1≤Dₖ₁≤3.3, and 0.002≤D_{f1}≤0.01.

In at least one embodiment, the first bonding layer 11 has a thickness of 12 μm to 50 μm.

A fusion temperature of the first bonding layer 11 is less than a fusion temperature of the insulating layer 21.

The insulating layer 21 may be made of a thermoplastic material having a low dielectric constant Dₖ₂ and a low dielectric loss factor D_{f2}. The thermoplastic material may be selected from a group consisting of liquid crystal polymer, modified polyimide, polyimide, epoxy resin, polyphenylene sulfide, polytetrafluoroethylene, and any combination thereof.

In at least one embodiment, Dₖ₂ of the insulating layer 21 and D_{f2} of the insulating layer 21 satisfy the following conditions: 2.1≤Dₖ₂≤3.3, and 0.002≤D_{f2}≤0.01.

In at least one embodiment, the insulating layer 21 has a thickness of 25 μm to 100 μm.

Preferably, the thickness of the first bonding layer 11 is less than the thickness of the insulating layer 21.

In at least one embodiment, a diameter of the blind via 31 is 75 mm to 150 mm.

The first wiring board 120 may be a flexible circuit board, a rigid circuit board or a flexible-rigid circuit board.

In at least one embodiment, the first wiring board 120 includes a first dielectric layer 41, a first outer wiring layer 43 and a second metal foil 42. The first outer wiring layer 43 and the second metal foil 42 are formed on opposite surfaces of the first dielectric layer 41, respectively. The first bonding layer 11 covers the first outer wiring layer 43 and is combined with the first dielectric layer 41.

In another embodiment, the first wiring board 120 may include other dielectric layers and other wiring layers.

In another embodiment, the second metal foil 42 may be replaced by a wiring layer.

Preferably, a thickness of the insulating layer 21 is less than a thickness of the first dielectric layer 41.

In at least one embodiment, a structure of the second wiring board 150 is the same with the structure of the connecting wiring board 110. The first bonding layer 11 of the second wiring board 150 covers the first inner wiring layer 23 and is combined with the insulating layer 21.

In at least one embodiment, a portion of the first wiring board 120 protrudes from the connecting wiring board 110 to expose from the connecting wiring board 110. The portion of the first wiring board 120 serves to carry at least one electronic element, and transmit an electrical signal between the electronic element and the connecting wiring board 110.

FIG. 13 illustrates an embodiment of a multilayer circuit board 200. The multilayer circuit board 200 includes a first wiring board 120, a connecting wiring board 130 and a second wiring board 140 stacked orderly. The first wiring board 120 and the second wiring board 140 may be a flexible circuit board, a rigid circuit board or a flexible-rigid circuit board, respectively.

In at least one embodiment, at least one electronic element may be amounted on at least one of the first wiring board 120 and the second wiring board 140.

In at least one embodiment, a portion of the first wiring board 120 protrudes from the connecting wiring board 130 to expose from the connecting wiring board 130. The portion of the first wiring board 120 serves to carry at least one electronic element, and transmit an electrical signal between the electronic element and the connecting wiring board 130.

In at least one embodiment, the connecting wiring board 130 includes a first bonding layer 11, an insulating layer 21, and a second bonding layer 61 stacked orderly. A fusion temperature of the first bonding layer 11 and a fusion temperature of the second bonding layer 61 are less than a fusion temperature of the insulating layer 21, respectively.

The first bonding layer 11 includes a first resin and a first insulating filler dispersed in the first resin. The first insulating filler serves to reduce a fluidity of the first bonding layer 11. The second bonding layer 61 includes a second resin and a second insulating filler dispersed in the second resin. The second insulating filler serves to reduce a fluidity of the second bonding layer 61.

In at least one embodiment, the first bonding layer 11 includes 15% by mass to 50% by mass of the first insulating filler. The second bonding layer 61 includes 15% by mass to 50% by mass of the second insulating filler.

In at least one embodiment, the first insulating filler is granular or fibrous. When the first insulating filler is granular, a diameter of the first insulating filler is 100 nm and 2 μm. When the first insulating filler is fibrous, a length of the first insulating filler is 100 nm and 2 μm.

In at least on embodiment, the first insulating filler may be silicon dioxide of different shapes and sizes.

In at least one embodiment, the first wiring board 120 includes a first dielectric layer 41, a first outer wiring layer 43 and a second metal foil 42. The first outer wiring layer 43 and the second metal foil 42 are formed on opposite surfaces of the first dielectric layer 41, respectively. The first bonding layer 11 covers the first outer wiring layer 43 and is combined with the first dielectric layer 41.

Preferably, a thickness of the insulating layer 21 is less than a thickness of the first dielectric layer 41.

In another embodiment, the first wiring board 120 may include other dielectric layers and other wiring layers.

In another embodiment, the second metal foil 42 may be replaced by a wiring layer or be omitted.

In at least one embodiment, the second wiring board 140 includes a third outer wiring layer 52, an second inner wiring layer 53, and a second outer wiring layer 55 stacked orderly and spaced. The second wiring board 140 further includes a second dielectric layer 54. The third outer wiring layer 52 and the second outer wiring layer 55 are located on opposite sides of the second dielectric layer 54. The second inner wiring layer 53 is embedded in the second dielectric layer 54, and wrapped by the second dielectric layer 54.

The second dielectric layer 54 is combined with the second bonding layer 61, the second outer wiring layer 55 is wrapped by the second dielectric layer 54 and the second bonding layer 61.

In another embodiment, the second wiring board 140 may include other dielectric layers and other wiring layers, or may only include the second outer wiring layer 55 and the second dielectric layer 54 but without the third outer wiring layer 52 and the second inner wiring layer 53.

In at least one embodiment, a material of the first dielectric layer 41 and a material of the second dielectric layer 54 may be respectively selected from a group consisting of liquid crystal polymer, modified polyimide, polyimide, epoxy resin, polyphenylene sulfide, polytetrafluoroethylene, and any combination thereof.

Preferably, a dielectric constant of the first dielectric layer 41 and a dielectric constant of the second dielectric layer 54 are between 2.1 and 3.3, respectively. A dielectric loss factor of the first dielectric layer 41 and a dielectric loss factor of the second dielectric layer 54 are between 0.002 and 0.01, respectively.

A fusion temperature of the first bonding layer 11 is less than a fusion temperature of the first dielectric layer 41 and less than a fusion temperature of the second dielectric layer 54.

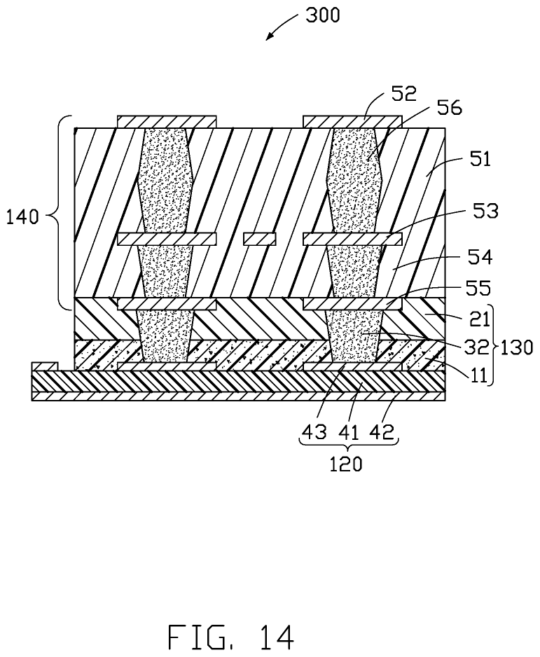

FIG. 14 illustrates another embodiment of a multilayer circuit board 300. A structure of the multilayer circuit board 300 is similar to a structure of the multilayer circuit board 200, except that the connecting wiring board 130 only include the insulating layer 21 and the first bonding layer 11 but without the second bonding layer 61.

Because the first bonding layer 11 includes the first insulating filler, the fluidity of the first bonding layer 11 is reduced. So that the first bonding layer 11 can provide a supporting force to the outer wiring layer, and reduce a wiring deviation caused by the flow of the first bonding layer 11 when pressing. In addition, the fusion temperature of the insulating layer 21 is greater than the fusion temperature of the first bonding layer 11 and the pressing temperature, so that the wiring deviation is further reduced.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A multilayer circuit board comprising:
a first connecting wring board comprising a first bonding layer and a liquid crystal polymer layer formed on the first bonding layer, wherein the first bonding layer comprises a first insulating filler, a fusion temperature of the first bonding layer is less than a fusion temperature of the liquid crystal polymer;
a first wiring board and a second wiring board disposed on opposite sides of the first connecting wiring board, wherein the first wiring board is combined with the first bonding layer.

2. The multilayer circuit board of claim 1, wherein the first bonding layer comprises a first resin, the first insulating filler dispersed in the first resin to reduce a fluidity of the first bonding layer.

3. The multilayer circuit board of claim 2, wherein the first bonding layer includes 15% by mass to 50% by mass of the first insulating filler.

4. The multilayer circuit board of claim 2, wherein a dielectric constant Dₖ₁ of the first resin and a dielectric loss factor D_{f1} of the first resin satisfy the following conditions: 2.1≤Dₖ₁≤3.3, and 0.002≤D_{f1}≤0.01.

5. The multilayer circuit board of claim 1, wherein a dielectric constant Dₖ₂ of the liquid crystal polymer and a dielectric loss factor D_{f2} of the liquid crystal polymer satisfy the following conditions: 2.1≤Dₖ₂≤3.3, and 0.002≤D_{f2}≤0.01.

6. The multilayer circuit board of claim 1, wherein a thickness of the first bonding layer is less than a thickness of the liquid crystal polymer.

7. The multilayer circuit board of claim 1, wherein each of the first wiring board and the second wiring board comprises a dielectric layer, the dielectric layer is made of a thermoplastic material, the fusion temperature of the first bonding layer is less than a fusion temperature of the dielectric layer.

8. The multilayer circuit board of claim 1, wherein the connecting wiring board further comprises a second bonding layer formed on a surface of the first insulating facing away from the liquid crystal polymer, the second wiring board is combined with the second bonding layer, a fusion temperature of the second bonding layer is less than the fusion temperature of the liquid crystal polymer, the second bonding layer comprises a second insulating filler.

9. The multilayer circuit board of claim 8, wherein the second bonding layer comprises a second resin, the second insulating filler dispersed in the second resin to reduce a fluidity of the second bonding layer, the second bonding layer includes 15% by mass to 50% by mass of the second insulating filler.

10. The multilayer circuit board of claim 9, wherein a composition of the second bonding layer is the same as a composition of the first bonding layer.

11. A method for manufacturing a multilayer circuit board comprising:
providing a connecting wiring board comprising a first bonding layer and a liquid crystal polymer formed on the first bonding layer, wherein the first bonding layer comprises a first insulating filler, a fusion temperature of the first bonding layer is less than a fusion temperature of the liquid crystal polymer;
pressing a first wiring board and a second wiring board on opposite sides of the first connecting wiring board to obtain the multilayer circuit board, wherein the first bonding layer is fused and combined with the first wiring board.

12. The method for manufacturing a multilayer circuit board of claim 11, wherein the first bonding layer comprises a first resin, the first insulating filler dispersed in the first resin to reduce a fluidity of the first bonding layer.

13. The method for manufacturing a multilayer circuit board of claim 12, wherein the first bonding layer includes 15% by mass to 50% by mass of the first insulating filler.

14. The method for manufacturing a multilayer circuit board of claim 12, wherein a dielectric constant Dₖ₁ of the first resin and a dielectric loss factor D_{f1} of the first resin satisfy the following conditions: 2.1≤Dₖ₁≤3.3, and 0.002≤D_{f1}≤0.01, a dielectric constant Dₖ₂ of the liquid crystal polymer and a dielectric loss factor D_{f2} of the liquid crystal polymer satisfy the following conditions: 2.1≤Dₖ₂≤3.3, and 0.002≤D_{f2}≤0.01.

15. The method for manufacturing a multilayer circuit board of claim 11, wherein at least one conductive paste passes through the first bonding layer and the liquid crystal polymer, and protrudes from a surface of the first bonding layer facing away from the liquid crystal polymer.

16. The method for manufacturing a multilayer circuit board of claim 11, wherein a thickness of the first bonding layer is less than a thickness of the liquid crystal polymer.

17. The method for manufacturing a multilayer circuit board of claim 11, wherein each of the first wiring board and the second wiring board comprises a dielectric layer, the dielectric layer is made of a thermoplastic material, the fusion temperature of the first bonding layer is less than a fusion temperature of the dielectric layer.

18. The method for manufacturing a multilayer circuit board of claim 11, wherein the connecting wiring board further comprises a second bonding layer formed on a surface of the first insulating facing away from the liquid crystal polymer, the second bonding layer comprises a second insulating filler, a fusion temperature of the second bonding layer is less than the fusion temperature of the liquid crystal polymer, when pressing a first wiring board and a second wiring board on opposite sides of the first connecting wiring board, the second bonding layer is fused and combined with the second wiring board.

19. The method for manufacturing a multilayer circuit board of claim 18, wherein the second bonding layer comprises a second resin, the second insulating filler dispersed in the second resin to reduce a fluidity of the second bonding layer, the second bonding layer includes 15% by mass to 50% by mass of the second insulating filler.

20. The method for manufacturing a multilayer circuit board of claim 19, wherein a composition of the second bonding layer is the same as a composition of the first bonding layer.
